(19) United States
(12) Patent Application Publication
(10) Pub. No.: US 2022/0415958 A1
(43) Pub. Date: Dec. 29, 2022

(54) SOLID-STATE IMAGING ELEMENT AND ELECTRONIC DEVICE

(71) Applicant: SONY SEMICONDUCTOR SOLUTIONS CORPORATION, KANAGAWA (JP)

(72) Inventor: SHIGEHIRO IKEHARA, KANAGAWA (JP)

(21) Appl. No.: 17/756,408

(22) PCT Filed: Nov. 27, 2020
(86) PCT No.: PCT/JP2020/044212

§ 371 Date: May 24, 2022

(30) Foreign Application Priority Data
Dec. 5, 2019 (JP) 2019-220215

(51) Int. Cl. H01L 27/146

(52) U.S. Cl. CPC H01L 27/14667; H01L 27/14627; H01L 27/1461; H01L 27/14647

(57) ABSTRACT

A solid-state imaging element (1) according to the present disclosure includes a photoelectric conversion unit (42) that converts incident light (L) into an electrical signal, and a stacked film group (43) provided on a light incident side of the photoelectric conversion unit (42). The stacked film group (43) is formed by stacking a plurality of stacked films (43a) formed by stacking thin films of different materials (M1, M2). An entire film thickness of the stacked film (43a) is smaller than a wavelength of the incident light (L).

### FIELD

The present disclosure relates to a solid-state imaging element and an electronic device.

### BACKGROUND

In recent years, in a solid-state imaging element used for an image sensor of a camera or the like, a structure having a transparent optical film in which refractive index is changed stepwise, the film being stacked on a light incident side of a photoelectric conversion layer, has been proposed (see, for example, Patent Literature 1).

### CITATION LIST

### Patent Literature

Patent Literature 1: JP 2009-260445 A

### SUMMARY

### Technical Problem

However, even in a case where thin films having different refractive indexes are stacked stepwise as in the above-described conventional technology, since there is a difference in refractive index at the interface between the thin films, incident light is reflected at the interface having such a difference in refractive index, and the light collection efficiency may decrease.

Therefore, the present disclosure proposes a solid-state imaging element and an electronic device capable of improving light collection efficiency to a photoelectric conversion unit.

### Solution to Problem

According to the present disclosure, there is provided a solid-state imaging element. The solid-state imaging element includes a photoelectric conversion unit that converts incident light into an electrical signal, and a stacked film group provided on a light incident side of the photoelectric conversion unit. The stacked film group is formed by stacking a plurality of stacked films formed by stacking thin films of different materials. An entire film thickness of the stacked film is smaller than a wavelength of the incident light.

### BRIEF DESCRIPTION OF DRAWINGS

FIG. 1 is a system configuration diagram illustrating a schematic configuration example of a solid-state imaging element according to an embodiment of the present disclosure.

FIG. 2 is a cross-sectional view schematically illustrating a structure of a pixel array unit according to an embodiment of the present disclosure.

FIG. 3 is an enlarged cross-sectional view schematically illustrating a stacked film group and a structure around the stacked film group in a pixel array unit according to an embodiment of the present disclosure.

FIG. 4 is a cross-sectional view schematically illustrating a structure of a pixel array unit according to a first modification of an embodiment of the present disclosure.

FIG. 5 is an enlarged cross-sectional view schematically illustrating a stacked film group and a structure around the stacked film group in the pixel array unit according to the first modification of the embodiment of the present disclosure.

FIG. 6 is a cross-sectional view schematically illustrating a structure of a pixel array unit according to a second modification of the embodiment of the present disclosure.

FIG. 7 is an enlarged cross-sectional view schematically illustrating a stacked film group and a structure around the stacked film group in the pixel array unit according to the second modification of the embodiment of the present disclosure.

FIG. 8 is a block diagram illustrating a configuration example of an imaging device as an electronic device to which the technology according to the present disclosure is applied.

FIG. 9 is a block diagram illustrating an example of a schematic configuration of a vehicle control system.

FIG. 10 is an explanatory diagram illustrating an example of installation positions of a vehicle exterior information detection unit and an imaging unit.

FIG. 11 is a diagram illustrating an example of a schematic configuration of an endoscopic surgical system.

FIG. 12 is a block diagram illustrating an example of functional configurations of a camera head and a CCU.

### DESCRIPTION OF EMBODIMENTS

Hereinafter, each embodiment of the present disclosure will be described in detail with reference to the drawings. In each of the following embodiments, the same portions are denoted by the same reference signs, and repetitive description will be omitted.

In recent years, in a solid-state imaging element used for an image sensor of a camera or the like, a structure having a transparent optical film in which refractive index is changed stepwise, the film being stacked on a light incident side of a photoelectric conversion layer, has been proposed.

However, even in a case where refractive indexes are stacked stepwise as in the above-described conventional technology, since there is a difference in refractive index at the interface between the layers, incident light is reflected at the interface having such a difference in refractive index, and the light collection efficiency may decrease.

Therefore, it is expected to achieve a technology capable of overcoming the above-described problem and improving the light collection efficiency to a photoelectric conversion unit.

[Configuration of Solid-State Imaging Element]

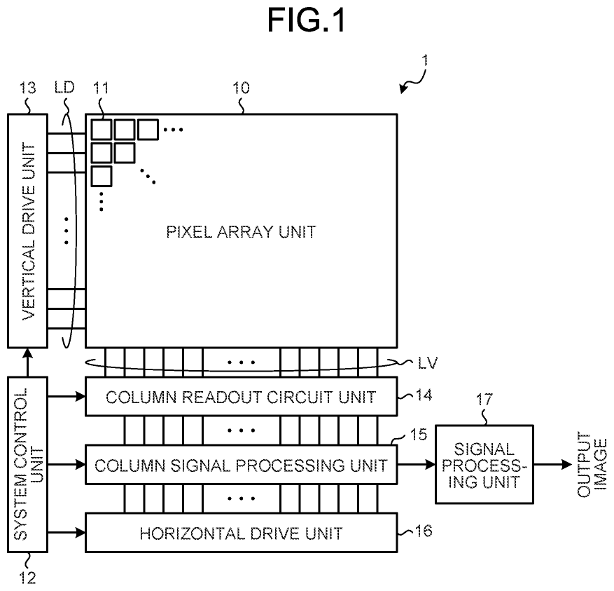

FIG. 1 is a system configuration diagram illustrating a schematic configuration example of a solid-state imaging element 1 according to an embodiment of the present disclosure. As illustrated in FIG. 1, the solid-state imaging element 1 that is a CMOS image sensor includes a pixel array unit 10, a system control unit 12, a vertical drive unit 13, a column readout circuit unit 14, a column signal processing unit 15, a horizontal drive unit 16, and a signal processing unit 17.

The pixel array unit 10, the system control unit 12, the vertical drive unit 13, the column readout circuit unit 14, the column signal processing unit 15, the horizontal drive unit 16, and the signal processing unit 17 are provided on a same semiconductor substrate or on a plurality of electrically connected and stacked semiconductor substrates.

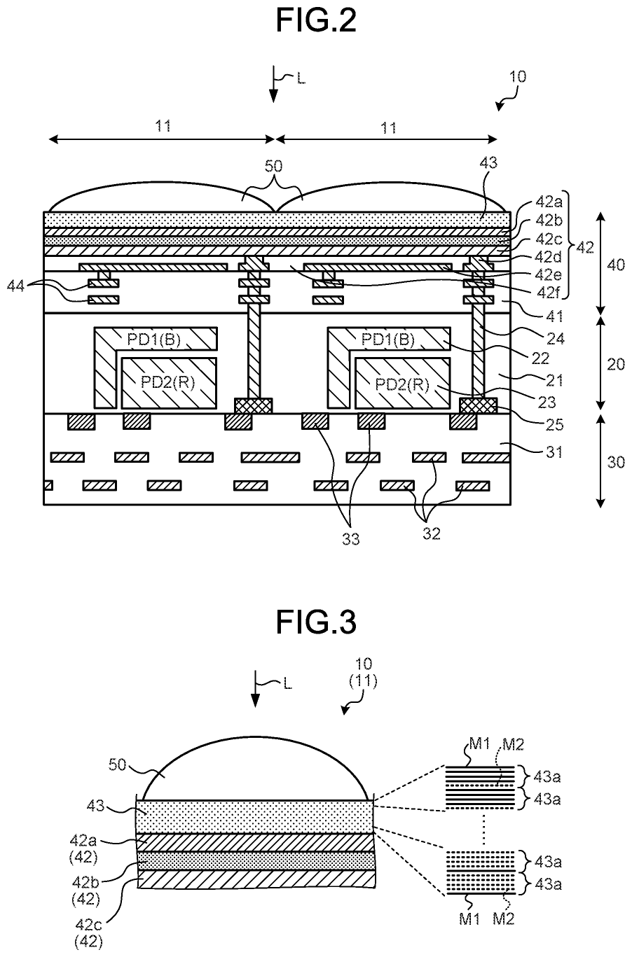

In the pixel array unit 10, effective unit pixels (hereinafter, these are also referred to as “unit pixels”) 11 each having a photoelectric conversion element (such as a photoelectric conversion unit 42 (see FIG. 2)) capable of photoelectrically converting a charge amount corresponding to an incident light amount, accumulating the charge amount therein, and outputting the charge amount as a signal are two-dimensionally arranged in a matrix.

In addition to the effective unit pixels 11, the pixel array unit 10 may include a region in which a dummy unit pixel having a structure without the photoelectric conversion unit 42 or the like, a light-shielding unit pixel in which its light receiving surface is shielded to block light incidence from the outside, or the like is arranged in a row and/or column.

Note that the light-shielding unit pixel may have the same configuration as the effective unit pixel 11 except for having a structure in which the light receiving surface is shielded from light. In addition, in the following description, the photoelectric charge having a charge amount according to an incident light amount is also simply referred to as “charge”, and the unit pixel 11 is also simply referred to as “pixel”.

In the pixel array unit 10, with respect to the pixel array in a matrix, a pixel drive line LD is formed for each row along the left-right direction in the drawing (the array direction of the pixels in the pixel row), and a vertical pixel wiring LV is formed for each column along the up-down direction in the drawing (the array direction of the pixels in the pixel column). One end of the pixel drive line LD is connected to an output end corresponding to each row of the vertical drive unit 13.

The column readout circuit unit 14 includes at least a circuit that supplies a constant current to the unit pixel 11 in a selected row in the pixel array unit 10 for each column, a current mirror circuit, a changeover switch of the unit pixel 11 to be read, and the like.

The column readout circuit unit 14 configures an amplifier together with a transistor in the selected pixel in the pixel array unit 10, converts the photoelectric charge signal into a voltage signal, and outputs the voltage signal to the vertical pixel wiring LV.

The vertical drive unit 13 includes a shift register, an address decoder, and the like, and drives the respective unit pixels 11 of the pixel array unit 10 at the same time for all the pixels or in units of rows. Although a specific configuration of the vertical drive unit 13 is not illustrated, the vertical drive unit 13 has a configuration including a readout scanning system and a sweep scanning system or a batch sweeping and batch transfer system.

The readout scanning system sequentially selects and scans the unit pixel 11 of the pixel array unit 10 row by row to read out a pixel signal from the unit pixel 11. In the case of row driving (rolling shutter operation), sweep scanning is performed on a readout row on which readout scanning is to be performed by the readout scanning system prior to the readout scanning by the time corresponding to a shutter speed.

In the case of global exposure (global shutter operation), batch sweeping is performed prior to batch transfer by the time of a shutter speed. By such sweeping, unnecessary charges are swept (reset) from the photoelectric conversion unit 42 and the like of the unit pixel 11 in the readout row. Then, a so-called electronic shutter operation is performed by sweeping (resetting) unnecessary charges.

Here, the electronic shutter operation refers to an operation of discarding unnecessary photoelectric charges accumulated in the photoelectric conversion unit 42 or the like until immediately before and newly starting exposure (starting accumulation of photoelectric charges).

The signal read out by the readout operation by the readout scanning system corresponds to the amount of light incident after the immediately preceding readout operation or electronic shutter operation. In the case of row driving, a period from the readout timing by the immediately preceding readout operation or the sweep timing by the electronic shutter operation to the readout timing by the current readout operation is a photoelectric charge accumulation time (exposure time) in the unit pixel 11. In the case of global exposure, the time from batch sweeping to batch transfer is the accumulation time (exposure time).

The pixel signal output from each unit pixel 11 of the pixel row selectively scanned by the vertical drive unit 13 is supplied to the column signal processing unit 15 through the corresponding vertical pixel wiring LV. The column signal processing unit 15 performs predetermined signal processing on the pixel signal output from each unit pixel 11 of the selected row through the vertical pixel wiring LV for each pixel column of the pixel array unit 10, and temporarily holds the pixel signal after the signal processing.

Specifically, the column signal processing unit 15 performs at least noise removal processing, for example, correlated double sampling (CDS) processing as the signal processing. By the CDS processing by the column signal processing unit 15, fixed pattern noise unique to pixels such as reset noise and threshold variation of an amplification transistor AMP is removed.

The column signal processing unit 15 can be configured to have, for example, an AD conversion function in addition to the noise removal processing and output the pixel signal as a digital signal.

The horizontal drive unit 16 includes a shift register, an address decoder, and the like, and sequentially selects a unit circuit corresponding to a pixel column of the column signal processing unit 15. By the selective scanning by the horizontal drive unit 16, pixel signals subjected to signal processing in the column signal processing unit 15 are sequentially output to the signal processing unit 17.

The system control unit 12 includes a timing generator that generates various timing signals and the like and performs drive control of the vertical drive unit 13, the column signal processing unit 15, the horizontal drive unit 16, and the like based on the various timing signals generated by the timing generator.

The solid-state imaging element 1 further includes the signal processing unit 17 and a data storage unit (not illustrated). The signal processing unit 17 has at least an addition processing function and performs various types of signal processing such as addition processing on the pixel signal output from the column signal processing unit 15.

The data storage unit temporarily stores data necessary for signal processing in the signal processing unit 17. The signal processing unit 17 and the data storage unit may be processing by an external signal processing unit provided on a substrate different from the solid-state imaging element 1, for example, a digital signal processor (DSP) or software, or may be mounted on the same substrate as the solid-state imaging element 1.

[Configuration of Pixel Array Unit]

Next, a detailed configuration of the pixel array unit 10 will be described with reference to FIG. 2. FIG. 2 is a cross-sectional view schematically illustrating a structure of the pixel array unit 10 according to an embodiment of the present disclosure.

The pixel array unit 10 includes a semiconductor layer 20, a wiring layer 30, an organic photoelectric conversion layer 40, and an on-chip lens (OCL) 50. In the pixel array unit 10, the OCL 50, the organic photoelectric conversion layer 40, the semiconductor layer 20, and the wiring layer 30 are stacked in this order from the side on which incident light L from the outside is incident (hereinafter, also referred to as a light incident side).

The semiconductor layer 20 includes a semiconductor region 21 of a first conductivity type (for example, P-type) and semiconductor regions 22 and 23 of a second conductivity type (for example, N-type). In the semiconductor region 21 of the first conductivity type, the semiconductor regions 22 and 23 of the second conductivity type are stacked in the depth direction in units of pixels, whereby photodiodes PD1 and PD2 by PN junction are formed in the depth direction.

For example, the photodiode PD1 having the semiconductor region 22 as a charge accumulation region is a photoelectric conversion unit that receives and photoelectrically converts blue light, and the photodiode PD2 having the semiconductor region 23 as a charge accumulation region is a photoelectric conversion unit that receives and photoelectrically converts red light. The photodiodes PD1 and PD2 are formed separately for each pixel 11 of the pixel array unit 10.

The wiring layer 30 is disposed on the surface of the semiconductor layer 20 opposite to the light incident side. The wiring layer 30 is configured by forming a plurality of wiring films 32 and a plurality of pixel transistors 33 in an interlayer insulating film 31. The plurality of pixel transistors 33 performs reading out of charges accumulated in the photodiodes PD1 and PD2 and a charge accumulation unit 25 described later, and the like.

The organic photoelectric conversion layer 40 is disposed on the surface on the light incident side of the semiconductor layer 20. The organic photoelectric conversion layer 40 includes an interlayer insulating film 41, the photoelectric conversion unit 42, and a stacked film group 43. In the organic photoelectric conversion layer 40, the stacked film group 43, the photoelectric conversion unit 42, and the interlayer insulating film 41 are stacked in this order from the light incident side.

The interlayer insulating film 41 includes, for example, a single-layer film made of one of silicon oxide (SiO₂), TEOS, silicon nitride (SiN), silicon oxynitride (SiON), and the like, or a stacked film made of two or more of these.

The interlayer insulating film 41 desirably has a small interface state to reduce the interface state with the semiconductor layer 20 and suppress generation of dark current from the interface with the semiconductor layer 20.

The photoelectric conversion unit 42 includes an upper electrode 42a, a photoelectric conversion layer 42b, a charge accumulation layer 42c, lower electrodes 42d and 42e, and an insulating layer 42f. In the photoelectric conversion unit 42, the upper electrode 42a, the photoelectric conversion layer 42b, the charge accumulation layer 42c, the insulating layer 42f, and the lower electrodes 42d and 42e are stacked in this order from the light incident side.

The upper electrode 42a, the photoelectric conversion layer 42b, the charge accumulation layer 42c, and the insulating layer 42f are formed in common in all the pixels 11 of the pixel array unit 10, and the lower electrodes 42d and 42e are formed separately for each pixel 11 of the pixel array unit 10.

The upper electrode 42a is electrically connected to the wiring film 32 of the wiring layer 30 via a wiring layer, a through electrode (both not illustrated), or the like at the peripheral edge portion of the pixel array unit 10. As a material of the upper electrode 42a, for example, a transparent conductive material such as indium tin oxide (ITO) is used.

The material of the upper electrode 42a and the lower electrode 42d is not limited to ITO, and various transparent conductive materials (for example, tin oxide (SnO₂), zinc oxide (ZnO), IZO, IGO, IGZO, ATO, AZO) can be used.

The IZO is an oxide obtained by adding indium to zinc oxide, the IGO is an oxide obtained by adding indium to gallium oxide, and the IGZO is an oxide obtained by adding indium and gallium to zinc oxide. The ATO is an oxide obtained by adding antimony to tin oxide, and the AZO is an oxide obtained by adding antimony to zinc oxide.

The photoelectric conversion layer 42b is made of an organic semiconductor material, and photoelectrically converts light having a selective wavelength (for example, green) among the incident light L from the outside.

The photoelectric conversion layer 42b desirably includes one or both of a p-type organic semiconductor and an n-type organic semiconductor. The photoelectric conversion layer 42b is made of, for example, quinacridone, a quinacridone derivative, a subphthalocyanine, a subphthalocyanine derivative, or the like, and desirably contains at least one of these materials.

The material of the photoelectric conversion layer 42b is not limited to such materials, and may be, for example, at least one of naphthalene, anthracene, phenanthrene, tetracene, pyrene, perylene, fluoranthene, and the like (all including derivatives).

For the photoelectric conversion layer 42b, a polymer or a derivative of phenylenevinylene, fluorene, carbazole, indole, pyrene, pyrrole, picoline, thiophene, acetylene, diacetylene, or the like may be used.

For the photoelectric conversion layer 42b, a metal complex dye, a cyanine-based dye, a merocyanine-based dye, a phenylxanthene-based dye, a triphenylmethane-based dye, a rhodacyanine-based dye, a xanthene-based dye, or the like may be used.

Examples of the metal complex dye include a dithiol metal complex dye, a metal phthalocyanine dye, a metal porphyrin dye, and a ruthenium complex dye. The photoelectric conversion layer 42b may contain other organic materials such as fullerene (C₆₀) and bathocuproine (BCP) in addition to such an organic semiconductor dye.

When green light is photoelectrically converted by the photoelectric conversion layer 42b, for example, a rhodamine-based dye, a melacyanine-based dye, a quinacridone derivative, a subphthalocyanine-based dye (subphthalocyanine derivative), or the like can be used for the photoelectric conversion layer 42b.

The charge accumulation layer 42c is provided between the photoelectric conversion layer 42b and the insulating layer 42f, and accumulates the charge generated in the photoelectric conversion layer 42b. The charge accumulation layer 42c is preferably formed using a material having higher charge mobility and a larger band gap than the photoelectric conversion layer 42b.

For example, the band gap of the constituent material of the charge accumulation layer 42c is preferably 3.0 eV or more. Examples of such a material include an oxide semiconductor material such as IGZO and an organic semiconductor material.

Examples of the organic semiconductor material include transition metal dichalcogenides, unit silicon (SiC), diamond, graphene, carbon nanotubes, condensed polycyclic hydrocarbon compounds, and condensed heterocyclic compounds.

By providing such a charge accumulation layer 42c below the photoelectric conversion layer 42b, it is possible to prevent recombination of charges at the time of charge accumulation and improve transfer efficiency.

As the material of the lower electrodes 42d and 42e, the same material as that of the upper electrode 42a (for example, ITO) is used. The lower electrode 42d is electrically connected to the charge accumulation layer 42c and is electrically connected to a metal wiring 24 penetrating the interlayer insulating film 41 and the semiconductor layer 20.

The metal wiring 24 is formed using a material such as tungsten (W), titanium (Ti), aluminum (Al), or copper (Cu). The metal wiring 24 also has a function as an inter-pixel light-shielding film.

In addition, the metal wiring 24 is electrically connected to the charge accumulation unit 25 formed in the vicinity of the interface on the side opposite to the light incident side of the semiconductor region 21. The charge accumulation unit 25 is formed of a semiconductor region of a second conductivity type (for example, N-type).

The lower electrode 42e is electrically connected to the wiring film 32 of the wiring layer 30 via a wiring film 44 formed in the interlayer insulating film 41, a through electrode (not illustrated), or the like.

The charge generated by photoelectric conversion by the photoelectric conversion unit 42 is transferred to the charge accumulation unit 25 via the metal wiring 24. The charge accumulation unit 25 temporarily accumulates the charge photoelectrically converted by the photoelectric conversion unit 42 until the charge is read out by the corresponding pixel transistor 33.

Specifically, in the photoelectric conversion unit 42, a predetermined voltage is applied from a drive circuit (not illustrated) to the lower electrodes 42d and 42e and the upper electrode 42a in a charge accumulation period. For example, in the charge accumulation period, a positive voltage is applied to the lower electrodes 42d and 42e, and a negative voltage is applied to the upper electrode 42a. Further, in the charge accumulation period, a larger positive voltage is applied to the lower electrode 42e than the lower electrode 42d.

As a result, in the charge accumulation period, electrons included in the charge generated by photoelectric conversion in the photoelectric conversion layer 42b are attracted by the large positive voltage of the lower electrode 42e and accumulated in the charge accumulation layer 42c.

In addition, in the pixel 11, a reset operation is performed by operating a reset transistor (not illustrated) in the late stage of the charge accumulation period. As a result, the potential of the charge accumulation unit 25 is reset, and the potential of the charge accumulation unit 25 becomes the power source voltage.

In the pixel 11, a charge transfer operation is performed after the reset operation is completed. In the charge transfer operation, a positive voltage higher than that of the lower electrode 42e is applied from the drive circuit to the lower electrode 42d. As a result, the electrons accumulated in the charge accumulation layer 42c are transferred to the charge accumulation unit 25 via the lower electrode 42d and the metal wiring 24.

In the pixel 11, a series of operations such as a charge accumulation operation, a reset operation, and a charge transfer operation is completed by the above operation.

The stacked film group 43 is provided between the upper electrode 42a of the photoelectric conversion unit 42 and the OCL 50. Details of the stacked film group 43 will be described later.

The OCL 50 having a hemispherical shape is a lens that is provided for each pixel 11 and condenses the incident light L on the photoelectric conversion unit 42, the photodiode PD1, and the photodiode PD2 of each pixel 11. The OCL 50 is made of, for example, an acrylic resin or the like.

[Configuration of Stacked Film Group]

Next, a detailed configuration of the stacked film group 43 will be described with reference to FIG. 3. FIG. 3 is an enlarged cross-sectional view schematically illustrating the stacked film group 43 and a structure around the stacked film group 43 in the pixel array unit 10 according to an embodiment of the present disclosure.

As illustrated in FIG. 3, the stacked film group 43 is provided between the upper electrode 42a of the photoelectric conversion unit 42 and the OCL 50. That is, the stacked film group 43 is provided on the light incident side of the photoelectric conversion unit 42.

The stacked film group 43 is formed by stacking a plurality of stacked films 43a. The stacked film 43a is formed by stacking a material M1 and a material M2 which are different materials. Both the material M1 and the material M2 are materials having an optical transparency (that is, the target sensor is transparent to the wavelength band used for photoelectric conversion).

The entire film thickness of the stacked film 43a is smaller than the wavelength of the incident light L. For example, the film thickness of one layer formed of the material M1 or the material M2 is several angstroms, and the entire film thickness of the stacked film 43a is about several tens nm.

The stacked film 43a can be formed, for example, by using a method such as physical vapor deposition (PVD), chemical vapor deposition (CVD), or atomic layer deposition (ALD).

In the stacked film 43a according to the embodiment, films of different materials M1 and M2 may be formed by one type of film forming method, or films of different materials M1 and M2 may be formed by combining two or more types of film forming methods.

Here, in the embodiment, by using materials having different refractive indexes for the material M1 and the material M2 and appropriately controlling film formation conditions, as illustrated in FIG. 3, the stacking ratio of the material M1 and the material M2 in each stacked film 43a is sequentially changed in the stacking direction.

For example, on the light incident side (that is, on the OCL 50 side) in the stacked film group 43, the stacked film 43a in which the material M1 has a higher ratio (for example, M1:M2=4:1) than the material M2 is formed.

Then, in the embodiment, the stacking ratio of the material M1 and the material M2 in the stacked film 43a is sequentially changed in the stacking direction. As a result, the stacked film 43a in which the material M2 has a higher ratio (for example, M1:M2=1:4) than the material M1 is formed on the side (that is, on the upper electrode 42a side) opposite to the light incident side in the stacked film group 43.

Here, in the embodiment, since the entire film thickness of each stacked film 43a is smaller than the wavelength of the incident light L, the stacked film group 43 according to the embodiment has no substantial interface with the incident light L inside, and functions as one optical film whose refractive index gradually changes in the stacking direction.

For example, when the refractive index of the OCL 50 is 1.6 and the refractive index of the upper electrode 42a is 2.0, a material having a refractive index close to the OCL 50 (for example, aluminum oxide) is used as the material M1, and a material having a refractive index close to the upper electrode 42a (for example, silicon nitride) is used as the material M2.

As a result, the difference in refractive index at the interface between the OCL 50 and the stacked film group 43 can be reduced, and the difference in refractive index at the interface between the stacked film group 43 and the upper electrode 42a can be reduced.

Therefore, according to the embodiment, since the reflection of the incident light L at the interface between the OCL 50 and the stacked film group 43 and the interface between the stacked film group 43 and the upper electrode 42a can be suppressed, the light collection efficiency of the incident light L to the photoelectric conversion unit 42 can be improved.

Further, in the embodiment, since there is no substantial interface that reflects the incident light L inside the stacked film group 43, reflection of the incident light L inside the stacked film group 43 can be suppressed. Therefore, according to the embodiment, the light collection efficiency of the incident light L to the photoelectric conversion unit 42 can be improved.

In the embodiment, the entire film thickness of the stacked film 43a is preferably 20 nm or less. As a result, since the entire film thickness of the stacked film 43a can be made sufficiently smaller than the wavelength of the incident light L, reflection of the incident light L inside the stacked film group 43 can be further suppressed.

Therefore, according to the embodiment, the light collection efficiency of the incident light L to the photoelectric conversion unit 42 can be further improved.

In addition, in the embodiment, at least one of the materials M1 and M2 constituting the stacked film 43a preferably has a function of suppressing permeation of hydrogen gas. For example, aluminum oxide used for the material M1 as described above has a function of suppressing permeation of hydrogen gas.

This makes it possible to suppress entry of hydrogen gas from the outside into the charge accumulation layer 42c made of an oxide semiconductor material such as IGZO. Therefore, according to the embodiment, it is possible to prevent the operation of the photoelectric conversion unit 42 from becoming unstable due to oxygen defects caused by reduction of the charge accumulation layer 42c by hydrogen gas from the outside.

That is, in the embodiment, in addition to the function of improving the light collection efficiency, a function of protecting the charge accumulation layer 42c can be imparted to the stacked film group 43.

In addition, in the embodiment, at least one of the materials M1 and M2 constituting the stacked film 43a preferably has a function of absorbing light of a specific wavelength. For example, silicon nitride used for the material M2 as described above has a function of absorbing ultraviolet light.

As a result, it is possible to suppress the occurrence of damage to the photoelectric conversion layer 42b by irradiating the photoelectric conversion layer 42b made of an organic material with ultraviolet light at the time of dry etching process or the like in the manufacturing process of the pixel array unit 10.

That is, in the embodiment, in addition to the function of improving the light collection efficiency, a function of protecting the photoelectric conversion layer 42b can be imparted to the stacked film group 43. The light that can be absorbed by at least one of the materials M1 and M2 is not limited to ultraviolet light, and may be, for example, infrared light.

In the embodiment, the material that can be used for the material M1 is not limited to aluminum oxide, and the material that can be used for the material M2 is not limited to silicon nitride.

For example, as a material capable of suppressing permeation of hydrogen gas, silicon nitride, carbon-containing silicon oxide (SiOC), or an oxide semiconductor such as ITO can be used. As a material capable of absorbing ultraviolet light, a nitride such as aluminum nitride (AlN) can be used.

[Various Modifications]

<First Modification>

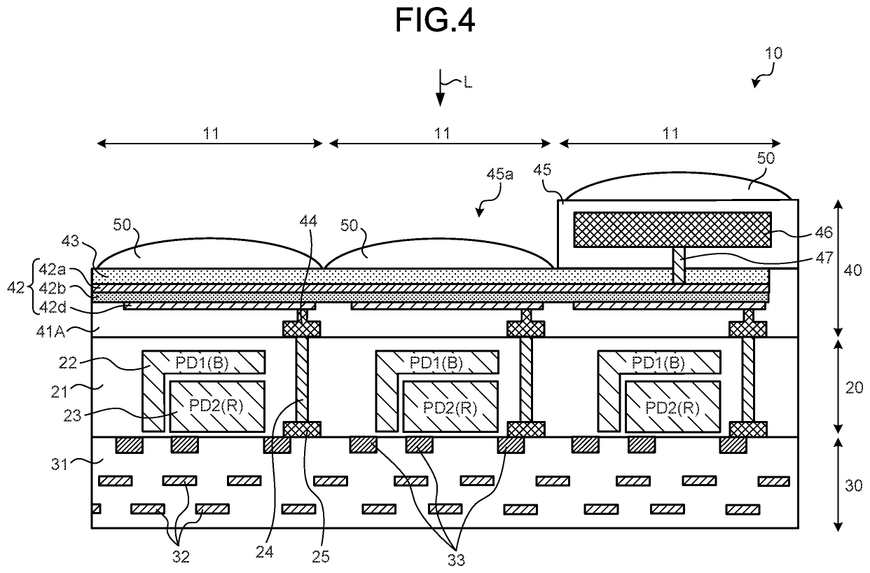

Next, various modifications of the embodiment will be described with reference to FIGS. 4 to 7. FIG. 4 is a cross-sectional view schematically illustrating a structure of the pixel array unit 10 according to a first modification of the embodiment of the present disclosure. In the first modification illustrated in FIG. 4, the structure of the organic photoelectric conversion layer 40 is different from that of the embodiment.

The organic photoelectric conversion layer 40 of the first modification includes a transparent insulating film 41A, the photoelectric conversion unit 42, the stacked film group 43, the wiring film 44, a sealing film 45, a light-shielding film 46, and a metal wiring 47.

The transparent insulating film 41A is formed of one layer or a plurality of layers using a material such as silicon oxide, silicon nitride, silicon oxynitride, or hafnium oxide (HfO₂). The transparent insulating film 41A desirably has a small interface state to reduce the interface state with the semiconductor layer 20 and suppress generation of dark current from the interface with the semiconductor layer 20.

The photoelectric conversion unit 42 is formed by stacking the upper electrode 42a, the photoelectric conversion layer 42b, and the lower electrode 42d in this order from the light incident side, and the photoelectric conversion layer 42b is disposed to be sandwiched between the upper electrode 42a and the lower electrode 42d.

The upper electrode 42a and the photoelectric conversion layer 42b are formed in common for all the pixels 11 of the pixel array unit 10, and the lower electrode 42d is formed separately for each of the pixels 11 of the pixel array unit 10.

As the materials of the upper electrode 42a and the lower electrode 42d, the same materials (for example, ITO) as those of the upper electrode 42a and the lower electrode 42d according to the embodiment are used.

The photoelectric conversion layer 42b is made of an organic semiconductor material, and photoelectrically converts light having a selective wavelength (for example, green) among the incident light L from the outside. As a material of the photoelectric conversion layer 42b, the same material as the material used in the embodiment is used.

In the photoelectric conversion unit 42, in addition to the upper electrode 42a, the photoelectric conversion layer 42b, and the lower electrode 42d, a charge blocking film, a buffer film, a work function adjustment film, and the like may be stacked. For example, an electron blocking film or an electron blocking/buffer film may be inserted between the upper electrode 42a and the photoelectric conversion layer 42b.

In addition, a hole blocking film, a hole blocking/buffer film, a work function adjustment film, or the like may be inserted between the photoelectric conversion layer 42b and the lower electrode 42d.

The lower electrode 42d is electrically connected to the wiring film 44 penetrating the transparent insulating film 41A, and the wiring film 44 is electrically connected to the metal wiring 24 penetrating the semiconductor region 21 of the semiconductor layer 20. The wiring film 44 is formed using a material such as tungsten, titanium, aluminum, or copper.

The metal wiring 24 is electrically connected to the charge accumulation unit 25 formed in the vicinity of the interface on the side opposite to the light incident side of the semiconductor region 21. The charge accumulation unit 25 is formed of a semiconductor region of a second conductivity type (for example, N-type).

The charge generated by photoelectric conversion in the photoelectric conversion unit 42 is transferred to the charge accumulation unit 25 via the wiring film 44 and the metal wiring 24. The charge accumulation unit 25 temporarily accumulates the charge photoelectrically converted by the photoelectric conversion unit 42 until the charge is read out by the corresponding pixel transistor 33.

The stacked film group 43 is provided on the surface on the light incident side of the upper electrode 42a of the photoelectric conversion unit 42. Details of the stacked film group 43 will be described later.

The sealing film 45 is provided on a part of the surface of the stacked film group 43. The remaining surface of the stacked film group 43 is provided with a cavity 45a formed by etching the sealing film 45 once formed is provided, and the OCL 50 is provided on the surface of the stacked film group 43 exposed at the bottom of the cavity 45a.

The sealing film 45 is made of an inorganic material having an optical transparency, for example, silicon nitride. The material of the sealing film 45 is not limited to silicon nitride, and various transparent inorganic materials (for example, silicon carbide oxide (SiCO), silicon carbide nitride (SiCN), silicon oxynitride, aluminum oxide, aluminum nitride) and the like can be used.

The light-shielding film 46 and a metal wiring 47 are provided inside the sealing film 45. The light-shielding film 46 is formed of a material having a light-shielding property (for example, a metal material), and is disposed in such a manner as to cover the photoelectric conversion unit 42 and the photodiodes PD1 and PD2 located on the back side of the sealing film 45.

The light-shielding film 46 and the upper electrode 42a are electrically connected by the metal wiring 47. Then, the OCL 50 is provided on the light incident side of the light-shielding film 46.

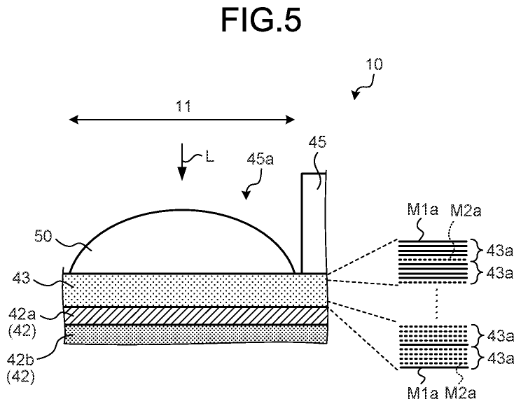

Next, a detailed configuration of the stacked film group 43 in the first modification will be described with reference to FIG. 5. FIG. 5 is an enlarged cross-sectional view schematically illustrating the stacked film group 43 and a structure around the stacked film group 43 in the pixel array unit 10 according to the first modification of the embodiment of the present disclosure.

As in the above-described embodiment, the stacked film group 43 of the first modification is provided between the upper electrode 42a of the photoelectric conversion unit 42 and the OCL 50. That is, the stacked film group 43 is provided on the light incident side of the photoelectric conversion unit 42.

The stacked film group 43 is formed by stacking a plurality of stacked films 43a. The stacked film 43a is formed by stacking a material M1a and a material M2a which are different materials. Both the material M1a and the material M2a are materials having an optical transparency (that is, the target sensor is transparent to the wavelength band used for photoelectric conversion).

The entire film thickness of the stacked film 43a is smaller than the wavelength of the incident light L. For example, the film thickness of one layer formed of the material M1a or the material M2a is several angstroms, and the entire film thickness of the stacked film 43a is about several tens nm.

Here, in the first modification, by using materials having different refractive indexes for the material M1a and the material M2a and appropriately controlling film formation conditions, as illustrated in FIG. 5, the stacking ratio of the material M1a and the material M2a in each stacked film 43a is sequentially changed in the stacking direction.

For example, on the light incident side (that is, on the OCL 50 side) in the stacked film group 43, the stacked film 43a in which the material M1a has a higher ratio (for example, M1a:M2a=4:1) than the material M2a is formed.

Then, in the first modification, the stacking ratio of the material M1a and the material M2a is sequentially changed in the stacking direction. As a result, the stacked film 43a in which the material M2a has a higher ratio (for example, M1a:M2a=1:4) than the material M1a is formed on the side (that is, on the upper electrode 42a side) opposite to the light incident side in the stacked film group 43.

Here, in the first modification, since the entire film thickness of each stacked film 43a is smaller than the wavelength of the incident light L, the stacked film group 43 according to the first modification has no substantial interface with the incident light L inside, and functions as one optical film whose refractive index gradually changes in the stacking direction.

For example, when the refractive index of the OCL 50 is 1.6 and the refractive index of the upper electrode 42a is 2.0, a material having a refractive index close to the OCL 50 (for example, aluminum oxide) is used as the material M1a, and a material having a refractive index close to the upper electrode 42a (for example, silicon nitride) is used as the material M2a.

As a result, the difference in refractive index at the interface between the OCL 50 and the stacked film group 43 can be reduced, and the difference in refractive index at the interface between the stacked film group 43 and the upper electrode 42a can be reduced.

Therefore, according to the first modification, since the reflection of the incident light L at the interface between the OCL 50 and the stacked film group 43 and the interface between the stacked film group 43 and the upper electrode 42a can be suppressed, the light collection efficiency of the incident light L to the photoelectric conversion unit 42 can be improved.

Further, in the first modification, since there is no substantial interface that reflects the incident light L inside the stacked film group 43, reflection of the incident light L inside the stacked film group 43 can be suppressed. Therefore, according to the first modification, the light collection efficiency of the incident light L to the photoelectric conversion unit 42 can be improved.

In the first modification, the entire film thickness of the stacked film 43a is preferably 20 nm or less. As a result, since the entire film thickness of the stacked film 43a can be made sufficiently smaller than the wavelength of the incident light L, reflection of the incident light L inside the stacked film group 43 can be further suppressed.

Therefore, according to the first modification, the light collection efficiency of the incident light L to the photoelectric conversion unit 42 can be further improved.

In the first modification, the etching rate of at least one of the materials M1a and M2a constituting the stacked film 43a for a predetermined etching processing is preferably lower than that of the film (here, the sealing film 45) stacked on the light incident side of the stacked film group 43.

For example, aluminum oxide used for the material M1a as described above has a lower etching rate for a dry etching process than the sealing film that is silicon nitride.

As a result, the material M1a of the stacked film group 43 can be used as an etching stopper when the sealing film 45 is subjected to dry etching process to form the cavity 45a. Therefore, according to the first modification, since it is not necessary to separately form an etching stopper film in the pixel array unit 10, it is possible to improve processing controllability when manufacturing the pixel array unit 10.

That is, in the first modification, in addition to the function of improving the light collection efficiency, a function of improving the shape (dimension) accuracy of the pixel array unit 10 can be imparted to the stacked film group 43.

In addition, in the first modification, at least one of the materials M1a and M2a constituting the stacked film 43a preferably has a function of absorbing light of a specific wavelength. For example, silicon nitride used for the material M2a as described above has a function of absorbing ultraviolet light.

As a result, it is possible to suppress the occurrence of damage to the photoelectric conversion layer 42b by irradiating the photoelectric conversion layer 42b made of an organic material with ultraviolet light at the time of dry etching process or the like in the manufacturing process of the pixel array unit 10.

That is, in the first modification, in addition to the function of improving the light collection efficiency, a function of protecting the photoelectric conversion layer 42b can be imparted to the stacked film group 43.

<Second Modification>

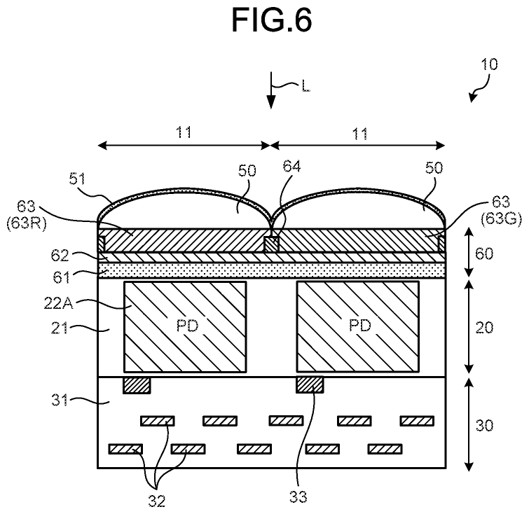

FIG. 6 is a cross-sectional view schematically illustrating a structure of the pixel array unit 10 according to a second modification of the embodiment of the present disclosure. The second modification illustrated in FIG. 6 is different from the embodiment in the structure of the semiconductor layer 20 and is different from the embodiment in that an optical layer 60 is stacked on the light incident side of the semiconductor layer 20.

The pixel array unit 10 according to the second modification includes the semiconductor layer 20, the wiring layer 30, the optical layer 60, and the OCL 50. In the pixel array unit 10, the OCL 50, the optical layer 60, the semiconductor layer 20, and the wiring layer 30 are stacked in this order from the light incident side.

The semiconductor layer 20 includes the semiconductor region 21 of a first conductivity type (for example, P-type) and a semiconductor region 22A of a second conductivity type (for example, N-type). In the semiconductor region 21 of the first conductivity type, the semiconductor region 22A of the second conductivity type is formed in units of pixels, whereby a photodiode PD by PN junction is formed. The photodiode PD is an example of a photoelectric conversion unit.

The optical layer 60 is disposed on the surface on the light incident side of the semiconductor layer 20. The optical layer 60 includes a stacked film group 61, a planarizing film 62, and a color filter 63. In the optical layer 60, the color filter 63, the planarizing film 62, and the stacked film group 61 are stacked in this order from the surface on the light incident side.

The stacked film group 61 is provided between the semiconductor region 21 of the semiconductor layer 20 and the planarizing film 62. Details of the stacked film group 61 will be described later.

The planarizing film 62 is provided to planarize the surface on which the color filter 63 is formed and to avoid unevenness generated in the rotational application process when the color filter 63 is formed. The planarizing film 62 is formed of, for example, silicon oxide.

The planarizing film 62 is not limited to the case of being formed of silicon oxide, and may be formed of silicon nitride, an organic material (for example, acrylic resin), or the like.

The color filter 63 is an optical filter that transmits light of a predetermined wavelength among the incident light L condensed by the OCL 50. The color filter 63 includes, for example, a color filter 63R that transmits red light, a color filter 63G that transmits green light, and a color filter (not illustrated) that transmits blue light.

Then, the color filters 63 that transmit the light of the respective colors are arranged in a predetermined array (for example, Bayer array) for respective pixels 11. In addition, a light-shielding wall 64 is provided between the color filters 63 of the respective pixels 11.

The light-shielding wall 64 is a wall-shaped film that shields light obliquely incident from adjacent pixels 11. By providing the light-shielding wall 64, it is possible to prevent incidence of light transmitted through the color filters 63 of the adjacent pixels 11, and thus, it is possible to prevent occurrence of color mixing. The light-shielding wall 64 is made of, for example, aluminum, tungsten, or the like.

The OCL 50 is a lens that is provided for each pixel 11 and condenses the incident light L on the photodiode PD of each pixel 11. The OCL 50 is made of, for example, an acrylic resin or the like.

In addition, in the second modification, a stacked film group 51 is formed on the surface on the light incident side of the OCL 50. Details of the stacked film group 51 will be described later.

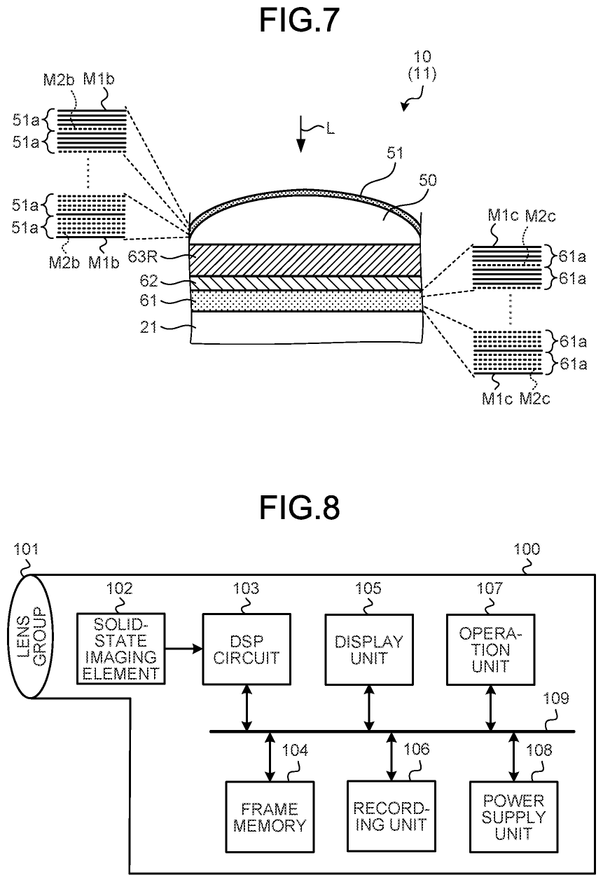

Next, detailed configurations of the stacked film groups 51 and 61 in the second modification will be described with reference to FIG. 7. FIG. 7 is an enlarged cross-sectional view schematically illustrating the stacked film groups 51 and 61 and structures around the stacked film groups 51 and 61 in the pixel array unit 10 according to the second modification of the embodiment of the present disclosure.

In the second modification, the stacked film group 51 is provided on the surface on the light incident side of the OCL 50, and the stacked film group 61 is provided between the semiconductor region 21 of the semiconductor layer 20 and the planarizing film 62. That is, the stacked film groups 51 and 61 are both provided on the light incident side of the photodiode PD as the photoelectric conversion unit.

The stacked film group 51 is formed by stacking a plurality of stacked films 51a. The stacked film 51a is formed by stacking a material M1b and a material M2b which are different materials. Both the material M1b and the material M2b are materials having an optical transparency (that is, the target sensor is transparent to the wavelength band used for photoelectric conversion).

The entire film thickness of the stacked film 51a is smaller than the wavelength of the incident light L. For example, the film thickness of one layer formed of the material M1b or the material M2b is several angstroms, and the entire film thickness of the stacked film 51a is about several tens nm.

Here, in the second modification, by using materials having different refractive indexes for the material M1b and the material M2b and appropriately controlling film formation conditions, as illustrated in FIG. 7, the stacking ratio of the material M1b and the material M2b in each stacked film 51a is sequentially changed in the stacking direction.

For example, on the light incident side (that is, on the air side) in the stacked film group 51, the stacked film 51a in which the material M1b has a higher ratio (for example, M1b:M2b=4:1) than the material M2b is formed.

Then, in the second modification, the stacking ratio of the material M1b and the material M2b is sequentially changed in the stacking direction. As a result, the stacked film 51a in which the material M2b has a higher ratio (for example, M1b:M2b=1:4) than the material M1b is formed on the side (that is, on the OCL 50 side) opposite to the light incident side in the stacked film group 51.

Here, in the second modification, since the entire film thickness of each stacked film 51a is smaller than the wavelength of the incident light L, the stacked film group 51 according to the second modification has no substantial interface with the incident light L inside, and functions as one optical film whose refractive index gradually changes in the stacking direction.

For example, when the refractive index of the air is 1.0 and the refractive index of the OCL 50 is 1.6, a material having a refractive index close to the air (for example, silicon oxide) is used as the material M1b, and a material having a refractive index close to the OCL 50 (for example, aluminum oxide) is used as the material M2b.

As a result, the difference in refractive index at the interface between the air and the stacked film group 51 can be reduced, and the difference in refractive index at the interface between the stacked film group 51 and the OCL 50 can be reduced.

Therefore, according to the second modification, since the reflection of the incident light L at the interface between the air and the stacked film group 51 and the interface between the stacked film group 51 and the OCL 50 can be suppressed, the light collection efficiency of the incident light L to the photodiode PD can be improved.

Further, in the second modification, since there is no substantial interface that reflects the incident light L inside the stacked film group 51, reflection of the incident light L inside the stacked film group 51 can be suppressed. Therefore, according to the second modification, the light collection efficiency of the incident light L to the photodiode PD can be improved.

In the second modification, the entire film thickness of the stacked film 51a is preferably 20 nm or less. As a result, since the entire film thickness of the stacked film 51a can be made sufficiently smaller than the wavelength of the incident light L, reflection of the incident light L inside the stacked film group 51 can be further suppressed.

Therefore, according to the second modification, the light collection efficiency of the incident light L to the photodiode PD can be further improved.

In addition, in the second modification, at least one of the materials M1b and M2b constituting the stacked film 51a preferably has a function of suppressing permeation of gas. For example, aluminum oxide used for the material M2b as described above has a function of suppressing permeation of gas.

As a result, entry of gas from the outside into the color filter 63 can be suppressed. Therefore, according to the second modification, it is possible to suppress deterioration of the color filter 63 due to gas from the outside.

That is, in the second modification, in addition to the function of improving the light collection efficiency, a function of protecting the color filter 63 can be imparted to the stacked film group 51.

Similarly to the stacked film group 51 described above, the stacked film group 61 is formed by stacking a plurality of stacked films 61a. The stacked film 61a is formed by stacking a material M1c and a material M2c which are different materials. Both the material M1c and the material M2c are materials having an optical transparency (that is, the target sensor is transparent to the wavelength band used for photoelectric conversion).

The entire film thickness of the stacked film 61a is smaller than the wavelength of the incident light L. For example, the film thickness of one layer formed of the material M1c or the material M2c is several angstroms, and the entire film thickness of the stacked film 61a is about several tens nm.

Here, in the second modification, by using materials having different refractive indexes for the material M1c and the material M2c and appropriately controlling film formation conditions, as illustrated in FIG. 7, the stacking ratio of the material M1c and the material M2c in each stacked film 61a is sequentially changed in the stacking direction.

For example, on the light incident side (that is, on the planarizing film 62 side) in the stacked film group 61, the stacked film 61a in which the material M1c has a higher ratio (for example, M1c:M2c=4:1) than the material M2c is formed.

Then, in the second modification, the stacking ratio of the material M1c and the material M2c is sequentially changed in the stacking direction. As a result, the stacked film 61a in which the material M2c has a higher ratio (for example, M1c:M2c=1:4) than the material M1c is formed on the side (that is, on the semiconductor region 21 side) opposite to the light incident side in the stacked film group 61.

Here, in the second modification, since the entire film thickness of each stacked film 61a is smaller than the wavelength of the incident light L, the stacked film group 61 according to the second modification has no substantial interface with the incident light L inside, and functions as one optical film whose refractive index gradually changes in the stacking direction.

For example, when the refractive index of the planarizing film 62 is 1.4 and the refractive index of the semiconductor region 21 is 3.9, a material having a refractive index close to the planarizing film 62 (for example, aluminum oxide) is used as the material M1c, and a material having a refractive index close to the semiconductor region 21 (for example, tantalum oxide (Ta₂O₅)) is used as the material M2c.

As a result, the difference in refractive index at the interface between the planarizing film 62 and the stacked film group 61 can be reduced, and the difference in refractive index at the interface between the stacked film group 61 and the semiconductor region 21 can be reduced.

Therefore, according to the second modification, since the reflection of the incident light L at the interface between the planarizing film 62 and the stacked film group 61 and the interface between the stacked film group 61 and the semiconductor region 21 can be suppressed, the light collection efficiency of the incident light L to the photodiode PD can be improved.

Further, in the second modification, since there is no substantial interface that reflects the incident light L inside the stacked film group 61, reflection of the incident light L inside the stacked film group 61 can be suppressed. Therefore, according to the second modification, the light collection efficiency of the incident light L to the photodiode PD can be improved.

In the second modification, the entire film thickness of the stacked film 61a is preferably 20 nm or less. As a result, since the entire film thickness of the stacked film 61a can be made sufficiently smaller than the wavelength of the incident light L, reflection of the incident light L inside the stacked film group 61 can be further suppressed.

Therefore, according to the second modification, the light collection efficiency of the incident light L to the photodiode PD can be further improved.

In the second modification, at least one of the materials M1c and M2c constituting the stacked film 61a preferably functions as a pinning layer for the photodiode PD. For example, tantalum oxide used for the material M2c as described above functions as a pinning layer for the photodiode PD.

As a result, carriers generated due to interface defects between the photodiode PD and the planarizing film 62 can be pinned, and therefore generation of dark current can be suppressed.

That is, in the second modification, in addition to the function of improving the light collection efficiency, a function of suppressing the generation of dark current can be imparted to the stacked film group 61.

In the second modification, at least one of the materials M1c and M2c constituting the stacked film 61a preferably has a function of adjusting stress generated in the photodiode PD. As a result, warping of the pixel array unit 10 at the time of manufacturing or the like can be suppressed, and therefore the manufacturing yield of the pixel array unit 10 can be improved.

That is, in the second modification, in addition to the function of improving the light collection efficiency, a function of improving the manufacturing yield of the pixel array unit 10 can be imparted to the stacked film group 61.

Note that, in the examples of FIGS. 6 and 7, an example in which both the stacked film group 51 and the stacked film group 61 are provided in the pixel array unit 10 has been described, but only either of the stacked film group 51 and the stacked film group 61 may be provided in the pixel array unit 10.

In the examples of FIGS. 6 and 7, an example in which a plurality of functions other than the optical characteristics are imparted to the stacked film group 51 and the stacked film group 61 has been described, but all of the plurality of functions other than optical characteristics do not have to be achieved simultaneously. For example, the stacked film group 61 may have only a function capable of suppressing generation of dark current in addition to optical characteristics but not a function of adjusting stress does.

In the embodiment and various modifications described above, examples in which the stacked films 43a, 51a, and 61a are made of two types of materials have been described, but the stacked films 43a, 51a, and 61a may be made of three or more types of materials.

As a result, since three or more kinds of functions can be imparted to the stacked film groups 43, 51, and 61, the stacked film groups 43, 51, and 61 can be further enhanced in functionality.

[Effect]

The solid-state imaging element 1 according to the embodiment includes the photoelectric conversion unit 42 (photodiodes PD, PD1, PD2) that converts the incident light L into an electrical signal, and the stacked film group 43 (51, 61) provided on the light incident side of the photoelectric conversion unit 42 (photodiodes PD, PD1, PD2). The stacked film group 43 (51, 61) is configured by stacking a plurality of stacked films 43a (51a, 61a) configured by stacking thin films of different materials M1 and M2 (M1a to M1c, M2a to M2c). The entire film thickness of the stacked film 43a (51a, 61a) is smaller than the wavelength of the incident light L.

This can improve the light collection efficiency to the photoelectric conversion unit 42 (photodiodes PD, PD1, PD2).

In the solid-state imaging element 1 according to the embodiment, the stacked film group 43 (51, 61) has an optical transparency and a refractive index that gradually changes in the stacking direction.

This can suppress reflection of the incident light L at the interface between the stacked film group 43 (51, 61) and each adjacent layer.

In the solid-state imaging element 1 according to the embodiment, at least one of the materials M1 and M2 constituting the stacked film 43a has a function of suppressing permeation of hydrogen gas.

This can impart a function of protecting the charge accumulation layer 42c to the stacked film group 43 in addition to the function of improving the light collection efficiency.

In the solid-state imaging element 1 according to the embodiment, at least one of the materials M1 and M2 (M1a, M2a) constituting the stacked film 43a has a function of absorbing light of a specific wavelength.

This can impart a function of protecting the photoelectric conversion layer 42b to the stacked film group 43 in addition to the function of improving the light collection efficiency.

In the solid-state imaging element 1 according to the embodiment, at least one of the materials M1 and M2 (M1a, M2a) constituting the stacked film 43a has a function of absorbing ultraviolet light.

This can suppress the occurrence of damage to the photoelectric conversion layer 42b by irradiating the photoelectric conversion layer 42b made of an organic material with ultraviolet light at the time of dry etching process or the like in the manufacturing process of the pixel array unit 10.

In the solid-state imaging element 1 according to the embodiment, at least one of the materials M1a and M2a constituting the stacked film 43a has a lower etching rate for a predetermined etching process than the film (sealing film 45) stacked on the light incident side of the stacked film group 43.

This can impart a function of improving the shape (dimension) accuracy of the pixel array unit 10 to the stacked film group 43 in addition to the function of improving the light collection efficiency.

In the solid-state imaging element 1 according to the embodiment, at least one of the materials M1c and M2c constituting the stacked film 61a functions as a pinning layer for the photoelectric conversion unit (photodiode PD).

This can impart a function of suppressing the generation of dark current to the stacked film group 61 in addition to the function of improving the light collection efficiency.

In the solid-state imaging element 1 according to the embodiment, at least one of the materials M1c and M2c constituting the stacked film 61a has a function of adjusting stress generated in the photoelectric conversion unit (photodiode PD).

This can impart a function of improving the manufacturing yield of the pixel array unit 10 to the stacked film group 61 in addition to the function of improving the light collection efficiency.

[Electronic Device]

The present disclosure is not limited to application to a solid-state imaging element. That is, the present disclosure is applicable to all electronic devices having a solid-state imaging element, such as a camera module, an imaging device, a portable terminal device having an imaging function, or a copying machine using a solid-state imaging element in an image reading unit, in addition to the solid-state imaging element.

Examples of such an imaging device include a digital still camera and a video camera. Examples of the portable terminal device having such an imaging function include a smartphone and a tablet terminal.

FIG. 8 is a block diagram illustrating a configuration example of an imaging device as an electronic device 100 to which the technology according to the present disclosure is applied. The electronic device 100 in FIG. 8 is, for example, an electronic device such as an imaging device for example a digital still camera or a video camera, or a portable terminal device for example a smartphone or a tablet terminal.

In FIG. 8, the electronic device 100 includes a lens group 101, a solid-state imaging element 102, a DSP circuit 103, a frame memory 104, a display unit 105, a recording unit 106, an operation unit 107, and a power supply unit 108.

In the electronic device 100, the DSP circuit 103, the frame memory 104, the display unit 105, the recording unit 106, the operation unit 107, and the power supply unit 108 are mutually connected via a bus line 109.

The lens group 101 captures incident light (image light) from an object and forms an image on an imaging surface of the solid-state imaging element 102. The solid-state imaging element 102 corresponds to the solid-state imaging element 1 according to the above-described embodiment and converts the amount of incident light imaged on the imaging surface by the lens group 101 into an electrical signal in units of pixels and outputs the electrical signal as a pixel signal.

The DSP circuit 103 is a camera signal processing circuit that processes the signal supplied from the solid-state imaging element 102. The frame memory 104 temporarily holds the image data processed by the DSP circuit 103 in units of frames.

The display unit 105 includes, for example, a panel type display device such as a liquid crystal panel or an organic electro luminescence (EL) panel and displays a moving image or a still image imaged by the solid-state imaging element 102. The recording unit 106 records image data of the moving image or the still image imaged by the solid-state imaging element 102 on a recording medium such as a semiconductor memory or a hard disk.

The operation unit 107 issues operation commands for various functions of the electronic device 100 in accordance with an operation by a user. The power supply unit 108 appropriately supplies various power sources serving as operation power sources of the DSP circuit 103, the frame memory 104, the display unit 105, the recording unit 106, and the operation unit 107 to these supply targets.

In the electronic device 100 configured in this manner, by applying the solid-state imaging element 1 of each of the above-described embodiments as the solid-state imaging element 102, it is possible to improve the light collection efficiency to the photoelectric conversion unit 42.

### Application Example to Mobile Body

The technology according to the present disclosure (present technology) can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a vessel, and a robot.

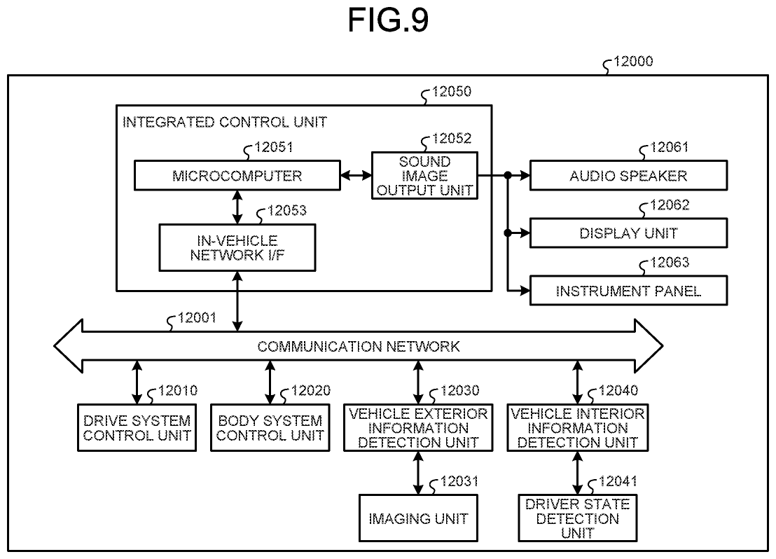

FIG. 9 is a block diagram illustrating a schematic configuration example of a vehicle control system which is an example of a mobile body control system to which the technology according to the present disclosure can be applied.

A vehicle control system 12000 includes a plurality of electronic control units connected via a communication network 12001. In the example illustrated in FIG. 9, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound image output unit 12052, and an in-vehicle network interface (I/F) 12053 are illustrated.

The drive system control unit 12010 controls the operation of devices related to the drive system of the vehicle according to various programs. For example, the drive system control unit 12010 functions as a control device of a driving force generation device for generating a driving force of the vehicle such as an internal combustion engine or a driving motor, a driving force transmission mechanism for transmitting the driving force to wheels, a steering mechanism for adjusting a steering angle of the vehicle, a braking device for generating a braking force of the vehicle, and the like.

The body system control unit 12020 controls operations of various devices mounted on the vehicle body according to various programs. For example, the body system control unit 12020 functions as a control device of a keyless entry system, a smart key system, a power window device, or various lamps such as a head lamp, a back lamp, a brake lamp, a blinker, and a fog lamp. In this case, radio waves transmitted from a portable device that substitutes for a key or signals of various switches can be input to the body system control unit 12020. The body system control unit 12020 receives input of these radio waves or signals, and controls a door lock device, a power window device, a lamp, and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing of a person, a vehicle, an obstacle, a sign, a character on a road surface, or the like on the basis of the received image.

The imaging unit 12031 is an optical sensor that receives light and outputs an electric signal corresponding to the amount of received light. The imaging unit 12031 can output the electric signal as an image or can output the electric signal as distance measurement information. The light received by the imaging unit 12031 may be visible light or invisible light such as infrared rays.

The vehicle interior information detection unit 12040 detects information inside the vehicle. For example, a driver state detection unit 12041 that detects a state of a driver is connected to the vehicle interior information detection unit 12040. The driver state detection unit 12041 includes, for example, a camera that images the driver, and the vehicle interior information detection unit 12040 may calculate the degree of fatigue or the degree of concentration of the driver or may determine whether or not the driver is dozing off on the basis of the detection information input from the driver state detection unit 12041.

The microcomputer 12051 can calculate a control target value of the driving force generation device, the steering mechanism, or the braking device on the basis of the information inside and outside the vehicle acquired by the vehicle exterior information detection unit 12030 or the vehicle interior information detection unit 12040 and output a control command to the drive system control unit 12010. For example, the microcomputer 12051 can perform cooperative control for the purpose of implementing functions of an advanced driver assistance system (ADAS) including collision avoidance or impact mitigation of the vehicle, follow-up traveling based on an inter-vehicle distance, vehicle speed maintenance traveling, vehicle collision warning, vehicle lane departure warning, or the like.

The microcomputer 12051 controls the driving force generation device, the steering mechanism, the braking device, or the like on the basis of the information around the vehicle acquired by the vehicle exterior information detection unit 12030 or the vehicle interior information detection unit 12040, thereby performing cooperative control for the purpose of automatic driving or the like in which the vehicle autonomously travels without depending on the operation of the driver.

In addition, the microcomputer 12051 can output a control command to the body system control unit 12020 on the basis of the vehicle exterior information acquired by the vehicle exterior information detection unit 12030. For example, the microcomputer 12051 can perform cooperative control for the purpose of preventing glare, such as switching from a high beam to a low beam, by controlling the head lamp according to the position of a preceding vehicle or an oncoming vehicle detected by the vehicle exterior information detection unit 12030.

The sound image output unit 12052 transmits an output signal of at least one of a sound or an image to an output device capable of visually or audibly notifying an occupant of the vehicle or the outside of the vehicle of information. In the example of FIG. 9, an audio speaker 12061, a display unit 12062, and an instrument panel 12063 are illustrated as the output device. The display unit 12062 may include, for example, at least one of an on-board display and a head-up display.

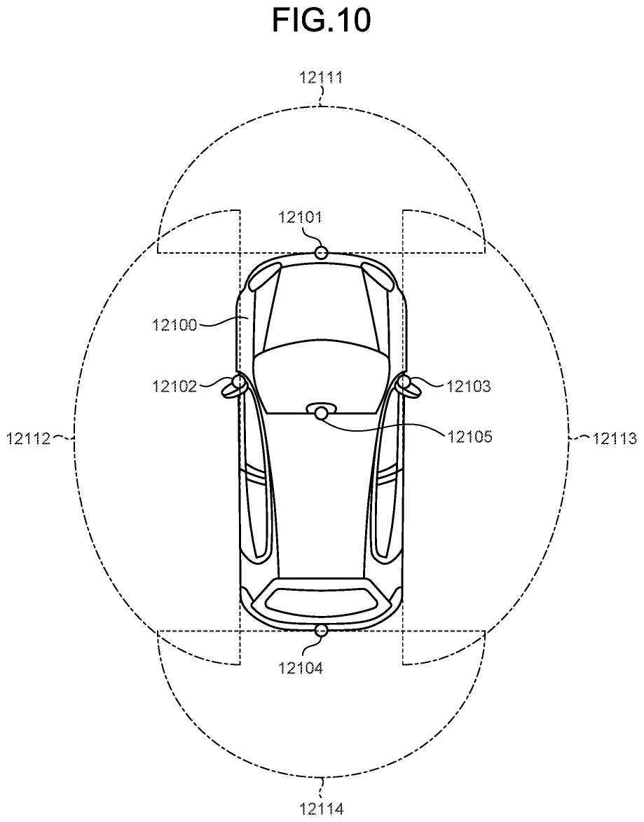

FIG. 10 is a diagram illustrating an example of an installation position of the imaging unit 12031.

In FIG. 10, imaging units 12101, 12102, 12103, 12104, and 12105 are included as the imaging unit 12031.

The imaging units 12101, 12102, 12103, 12104, and 12105 are provided, for example, at positions such as a front nose, a side mirror, a rear bumper, a back door, and an upper portion of a windshield in a vehicle interior of a vehicle 12100. The imaging unit 12101 provided at the front nose and the imaging unit 12105 provided at the upper portion of the windshield in the vehicle interior mainly acquire images in front of the vehicle 12100. The imaging units 12102 and 12103 provided at the side mirrors mainly acquire images of the sides of the vehicle 12100. The imaging unit 12104 provided on the rear bumper or the back door mainly acquires an image behind the vehicle 12100. The imaging unit 12105 provided at the upper portion of the windshield in the vehicle interior is mainly used to detect a preceding vehicle, a pedestrian, an obstacle, a traffic light, a traffic sign, a lane, or the like.

FIG. 10 illustrates an example of photographing ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 provided at the side mirrors, respectively, and an imaging range 12114 indicates an imaging range of the imaging unit 12104 provided at the rear bumper or the back door. For example, by superposing image data captured by the imaging units 12101 to 12104, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements or may be an imaging element having pixels for phase difference detection.

For example, the microcomputer 12051 obtains a distance to each three-dimensional object in the imaging ranges 12111 to 12114 and a temporal change of the distance (relative speed with respect to the vehicle 12100) on the basis of the distance information obtained from the imaging units 12101 to 12104, thereby extracting, as a preceding vehicle, a three-dimensional object traveling at a predetermined speed (for example, 0 km/h or more) in substantially the same direction as the vehicle 12100, in particular, the closest three-dimensional object on a traveling path of the vehicle 12100. Further, the microcomputer 12051 can set an inter-vehicle distance to be secured in advance behind the preceding vehicle and can perform automatic brake control (including follow-up stop control), automatic acceleration control (including follow-up start control), and the like. In this manner, it is possible to perform cooperative control for the purpose of automatic driving or the like in which the vehicle autonomously travels without depending on the operation of the driver.

For example, on the basis of the distance information obtained from the imaging units 12101 to 12104, the microcomputer 12051 can classify three-dimensional object data regarding three-dimensional objects into two-wheeled vehicles, ordinary vehicles, large vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that can be visually recognized by the driver of the vehicle 12100 and obstacles that are difficult to visually recognize. Then, the microcomputer 12051 determines a collision risk indicating a risk of collision with each obstacle, and when the collision risk is a set value or more and there is a possibility of collision, the microcomputer can perform driving assistance for collision avoidance by outputting an alarm to the driver via the audio speaker 12061 or the display unit 12062 or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not a pedestrian is present in the captured images of the imaging units 12101 to 12104. Such pedestrian recognition is performed by, for example, a procedure of extracting feature points in the captured images of the imaging units 12101 to 12104 as infrared cameras, and a procedure of performing pattern matching processing on a series of feature points indicating an outline of an object to determine whether or not the object is a pedestrian. When the microcomputer 12051 determines that a pedestrian is present in the captured images of the imaging units 12101 to 12104 and recognizes the pedestrian, the sound image output unit 12052 controls the display unit 12062 to superpose and display a square contour line for emphasis on the recognized pedestrian. The sound image output unit 12052 may control the display unit 12062 to display an icon or the like indicating a pedestrian at a desired position.

An example of the vehicle control system to which the technology according to the present disclosure can be applied has been described above. The technology according to the present disclosure can be applied to the imaging unit 12031 among the configurations described above. Specifically, the solid-state imaging element 1 in FIG. 1 can be applied to the imaging unit 12031. By applying the technology according to the present disclosure to the imaging unit 12031, a high-quality image can be acquired from the imaging unit 12031.

### Application Example to Endoscopic Surgical System

The technology according to the present disclosure (present technology) can be applied to various products. For example, the technology according to the present disclosure may be applied to an endoscopic surgical system.

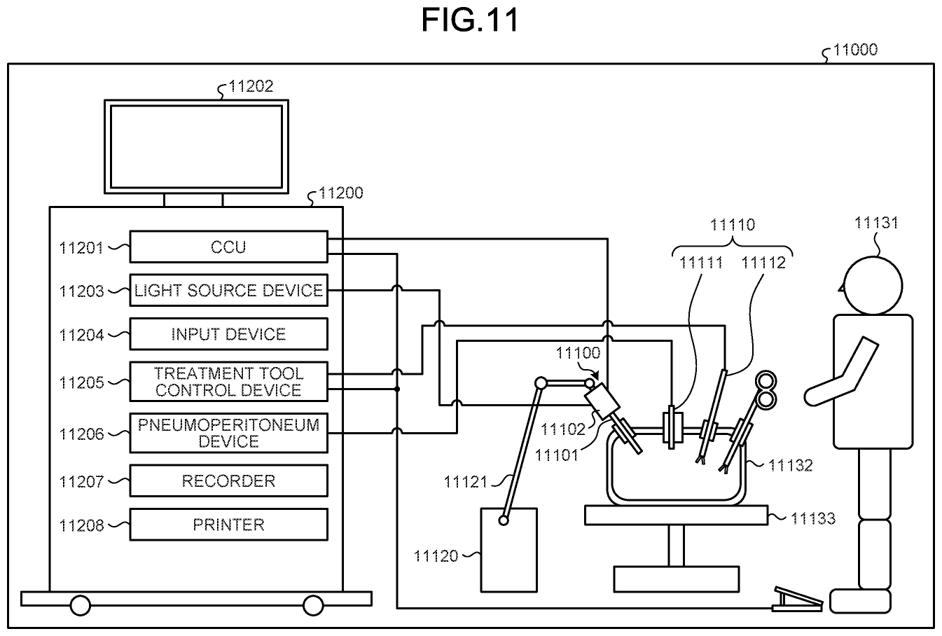

FIG. 11 is a diagram illustrating an example of a schematic configuration of an endoscopic surgical system to which the technology according to the present disclosure (the present technology) can be applied.

FIG. 11 illustrates a state in which an operator (doctor) 11131 is performing surgery on a patient 11132 on a patient bed 11133 using an endoscopic surgical system 11000. As illustrated, the endoscopic surgical system 11000 includes an endoscope 11100, other surgical tools 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 includes a lens barrel 11101 whose region of a predetermined length from the distal end is inserted into the body cavity of the patient 11132, and a camera head 11102 connected to the proximal end of the lens barrel 11101. In the illustrated example, the endoscope 11100 configured as a so-called rigid scope having the rigid lens barrel 11101 is illustrated, but the endoscope 11100 may be configured as a so-called flexible scope having a flexible lens barrel.

An opening portion into which an objective lens is fitted is provided at the distal end of the lens barrel 11101. A light source device 11203 is connected to the endoscope 11100, and light generated by the light source device 11203 is guided to the distal end of the lens barrel by a light guide extending inside the lens barrel 11101 and is emitted toward an observation target in the body cavity of the patient 11132 via the objective lens. The endoscope 11100 may be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system. The observation light is photoelectrically converted by the imaging element, and an electric signal corresponding to the observation light, that is, an image signal corresponding to the observation image is generated. The image signal is transmitted to a camera control unit (CCU) 11201 as RAW data.

The CCU 11201 includes a central processing unit (CPU), a graphics processing unit (GPU), and the like, and integrally controls operation of the endoscope 11100 and a display device 11202. Further, the CCU 11201 receives an image signal from the camera head 11102 and performs various types of image processing for displaying an image based on the image signal, such as development processing (demosaic processing), on the image signal.

The display device 11202 displays an image based on the image signal subjected to the image processing by the CCU 11201 under the control of the CCU 11201.

The light source device 11203 includes a light source such as a light emitting diode (LED), for example, and supplies irradiation light for photographing a surgical site or the like to the endoscope 11100.

An input device 11204 is an input interface for the endoscopic surgical system 11000. A user can input various types of information and instructions to the endoscopic surgical system 11000 via the input device 11204. For example, the user inputs an instruction or the like to change imaging conditions (type of irradiation light, magnification, focal length, and the like) by the endoscope 11100.

A treatment tool control device 11205 controls driving of the energy treatment tool 11112 for cauterization and incision of tissue, sealing of a blood vessel, or the like. A pneumoperitoneum device 11206 feeds gas into the body cavity of the patient 11132 via the pneumoperitoneum tube 11111 in order to inflate the body cavity for the purpose of securing a visual field by the endoscope 11100 and securing a working space of the operator. A recorder 11207 is a device capable of recording various types of information regarding surgery. A printer 11208 is a device capable of printing various types of information regarding surgery in various formats such as text, image, or graph.

The light source device 11203 that supplies the endoscope 11100 with the irradiation light at the time of photographing the surgical site can include, for example, an LED, a laser light source, or a white light source including a combination thereof. In a case where the white light source includes a combination of RGB laser light sources, since the output intensity and the output timing of each color (each wavelength) can be controlled with high accuracy, adjustment of the white balance of the captured image can be performed in the light source device 11203. In this case, by irradiating the observation target with the laser light from each of the RGB laser light sources in a time division manner and controlling the driving of the imaging element of the camera head 11102 in synchronization with the irradiation timing, it is also possible to capture an image corresponding to each of RGB in a time division manner. According to this method, a color image can be obtained without providing a color filter in the imaging element.

The driving of the light source device 11203 may be controlled so as to change the intensity of light to be output every predetermined time. By controlling the driving of the imaging element of the camera head 11102 in synchronization with the timing of the change of the light intensity to acquire images in a time division manner and synthesizing the images, it is possible to generate an image of a high dynamic range without so-called blocked up shadows and blown out highlights.

The light source device 11203 may be configured to be able to supply light in a predetermined wavelength band corresponding to special light observation. In the special light observation, for example, so-called narrow band imaging is performed in which a predetermined tissue such as a blood vessel in a mucosal surface layer is imaged with high contrast by irradiating light in a narrower band than irradiation light at the time of normal observation (that is, white light) using wavelength dependency of light absorption in a body tissue. Alternatively, in the special light observation, fluorescence observation for obtaining an image by fluorescence generated by irradiation with excitation light may be performed. In the fluorescence observation, it is possible to irradiate a body tissue with excitation light to observe fluorescence from the body tissue (autofluorescence observation), or to locally inject a reagent such as indocyanine green (ICG) into a body tissue and irradiate the body tissue with excitation light corresponding to a fluorescence wavelength of the reagent to obtain a fluorescent image, for example. The light source device 11203 can be configured to be able to supply narrow band light and/or excitation light corresponding to such special light observation.

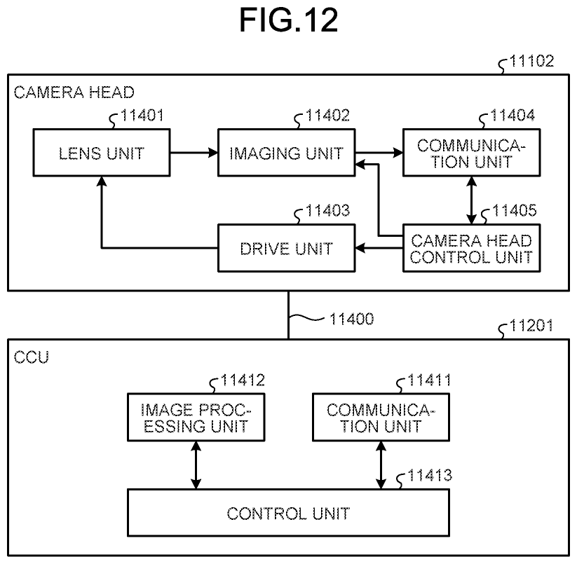

FIG. 12 is a block diagram illustrating an example of functional configurations of the camera head 11102 and the CCU 11201 illustrated in FIG. 11.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at a connection portion with the lens barrel 11101. Observation light taken in from the distal end of the lens barrel 11101 is guided to the camera head 11102 and enters the lens unit 11401. The lens unit 11401 is configured by combining a plurality of lenses including a zoom lens and a focus lens.

The number of imaging elements constituting the imaging unit 11402 may be one (so-called single-plate type) or plural (so-called multi-plate type). In a case where the imaging unit 11402 is configured as a multi-plate type, for example, image signals corresponding to RGB may be generated by the respective imaging elements, and a color image may be obtained by combining the image signals. Alternatively, the imaging unit 11402 may include a pair of image sensors for acquiring right-eye and left-eye image signals corresponding to three-dimensional (3D) display. Performing the 3D display enables the operator 11131 to grasp the depth of the living tissue in the surgical site more accurately. In a case where the imaging unit 11402 is configured as a multi-plate type, a plurality of lens units 11401 can be provided corresponding to the respective imaging elements.

The imaging unit 11402 is not necessarily provided in the camera head 11102. For example, the imaging unit 11402 may be provided immediately behind the objective lens inside the lens barrel 11101.

The drive unit 11403 includes an actuator and moves the zoom lens and the focus lens of the lens unit 11401 by a predetermined distance along the optical axis under the control of the camera head control unit 11405. This enables appropriate adjustment of the magnification and focus of the image captured by the imaging unit 11402.

The communication unit 11404 includes a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the control signal to the camera head control unit 11405. The control signal includes, for example, information regarding imaging conditions such as information for specifying a frame rate of a captured image, information for specifying an exposure value at the time of imaging, and/or information for specifying a magnification and a focus of a captured image.

The imaging conditions such as the frame rate, the exposure value, the magnification, and the focus may be appropriately specified by the user or may be automatically set by the control unit 11413 of the CCU 11201 on the basis of the acquired image signal. In the latter case, a so-called auto exposure (AE) function, an auto focus (AF) function, and an auto white balance (AWB) function are installed in the endoscope 11100.

The camera head control unit 11405 controls driving of the camera head 11102 on the basis of the control signal from the CCU 11201 received via the communication unit 11404.

The communication unit 11411 includes a communication device for transmitting and receiving various types of information to and from the camera head 11102. The communication unit 11411 receives an image signal transmitted from the camera head 11102 via the transmission cable 11400.

The communication unit 11411 transmits a control signal for controlling driving of the camera head 11102 to the camera head 11102. The image signal and the control signal can be transmitted by electric communication, optical communication, or the like.

The image processing unit 11412 performs various types of image processing on the image signal that is RAW data transmitted from the camera head 11102.

The control unit 11413 performs various types of control related to imaging of a surgical site or the like by the endoscope 11100 and display of a captured image obtained by imaging of the surgical site or the like. For example, the control unit 11413 generates a control signal for controlling driving of the camera head 11102.

The control unit 11413 causes the display device 11202 to display a captured image of a surgical site or the like on the basis of the image signal subjected to the image processing by the image processing unit 11412. At this time, the control unit 11413 may recognize various objects in the captured image using various image recognition technologies. For example, the control unit 11413 can recognize a surgical tool such as forceps, a specific body part, bleeding, mist at the time of using the energy treatment tool 11112, and the like by detecting the shape, color, and the like of the edge of the object included in the captured image. When displaying the captured image on the display device 11202, the control unit 11413 may superpose and display various types of surgery support information on the image of the surgical site by using the recognition result. With the superposed display of the surgery support information presented to the operator 11131, the burden on the operator 11131 can be reduced and the operator 11131 can reliably proceed with the surgery.

The transmission cable 11400 connecting the camera head 11102 and the CCU 11201 is an electric signal cable compatible with electric signal communication, an optical fiber compatible with optical communication, or a composite cable thereof.

Here, in the illustrated example, communication is performed by wire using the transmission cable 11400, but communication between the camera head 11102 and the CCU 11201 may be performed wirelessly.

An example of the endoscopic surgical system to which the technology according to the present disclosure can be applied has been described above. The technology according to the present disclosure can be applied to the imaging unit 11402 of the camera head 11102 among the above-described configurations. Specifically, the solid-state imaging element 1 in FIG. 1 can be applied to the imaging unit 11402. By applying the technology according to the present disclosure to the imaging unit 11402, a high-quality surgical site image can be obtained from the imaging unit 11402, and therefore the operator can reliably check the surgical site.

Note that, here, the endoscopic surgical system has been described as an example, but the technology according to the present disclosure may be applied to, for example, a microscopic surgical system or the like.

Although the above description is given regarding the embodiments of the present disclosure, the technical scope of the present disclosure is not limited to the above-described embodiments as they are, and various modifications can be made without departing from the scope of the present disclosure. In addition, the components in different embodiments and modifications may be appropriately combined.

The effects described in the present specification are merely examples and are not restrictive of the disclosure herein, and other effects may be achieved.

The present technology can also have the following configurations.

(1)

A solid-state imaging element comprising:

a photoelectric conversion unit that converts incident light into an electrical signal; and

a stacked film group provided on a light incident side of the photoelectric conversion unit, wherein

the stacked film group is formed by stacking a plurality of stacked films formed by stacking thin films of different materials, and

an entire film thickness of the stacked film is smaller than a wavelength of incident light.

(2)

The solid-state imaging element according to above (1), wherein

the stacked film group has an optical transparency and a refractive index that gradually changes in a stacking direction.

(3)

The solid-state imaging element according to above (2), wherein

at least one of the materials constituting the stacked film has a function of suppressing permeation of hydrogen gas.

(4)

The solid-state imaging element according to above (2) or (3), wherein

at least one of the materials constituting the stacked film has a function of absorbing light having a specific wavelength.

(5)

The solid-state imaging element according to above (4), wherein

at least one of the materials constituting the stacked film has a function of absorbing ultraviolet light.

(6)

The solid-state imaging element according to any one of the above (2) to (5), wherein

at least one of the materials constituting the stacked film has a lower etching rate for a predetermined etching process than a film stacked on a light incident side of the stacked film group.

(7)

The solid-state imaging element according to any one of the above (2) to (6), wherein

at least one of the materials constituting the stacked film functions as a pinning layer for the photoelectric conversion unit.

(8)

The solid-state imaging element according to any one of the above (2) to (7), wherein

at least one of the materials constituting the stacked film has a function of adjusting stress generated in the photoelectric conversion unit.

(9)

An electronic device comprising:

a solid-state imaging element;

an optical system that captures incident light from an object and forms an image on an imaging surface of the solid-state imaging element; and

a signal processing circuit that performs processing on an output signal from the solid-state imaging element,

the solid-state imaging element including:

a photoelectric conversion unit that converts incident light into an electrical signal; and

a stacked film group provided on a light incident side of the photoelectric conversion unit,

wherein the stacked film group is formed by stacking a plurality of stacked films formed by stacking thin films of different materials, and

an entire film thickness of the stacked film is smaller than a wavelength of incident light.

(10)

The electronic device according to above (9), wherein

the stacked film group has an optical transparency and a refractive index that gradually changes in a stacking direction.

(11)

The electronic device according to above (10), wherein

at least one of the materials constituting the stacked film has a function of suppressing permeation of hydrogen gas.

(12)

The electronic device according to above (10) or (11), wherein

at least one of the materials constituting the stacked film has a function of absorbing light having a specific wavelength.

(13)

The electronic device according to above (12), wherein

at least one of the materials constituting the stacked film has a function of absorbing ultraviolet light.

(14)

The electronic device according to any one of above (10) to (13), wherein

at least one of the materials constituting the stacked film has a lower etching rate for a predetermined etching process than a film stacked on a light incident side of the stacked film group.

(15)

The electronic device according to any one of above (10) to (14), wherein

at least one of the materials constituting the stacked film functions as a pinning layer for the photoelectric conversion unit.

(16)

The electronic device according to any one of above (10) to (15), wherein

at least one of the materials constituting the stacked film has a function of adjusting stress generated in the photoelectric conversion unit.

### REFERENCE SIGNS LIST

1 SOLID-STATE IMAGING ELEMENT
10 PIXEL ARRAY UNIT
11 UNIT PIXEL
42 PHOTOELECTRIC CONVERSION UNIT
43, 51, 61 STACKED FILM GROUP
43a, 51a, 61a STACKED FILM
45 SEALING FILM
100 ELECTRONIC DEVICE
M1, M1a to M1c, M2, M2a to M2c MATERIAL
PD, PD1, PD2 PHOTODIODE (AN EXAMPLE OF PHOTOELECTRIC CONVERSION UNIT)

1. A solid-state imaging element comprising:
a photoelectric conversion unit that converts incident light into an electrical signal; and
a stacked film group provided on a light incident side of the photoelectric conversion unit, wherein
the stacked film group is formed by stacking a plurality of stacked films formed by stacking thin films of different materials, and
an entire film thickness of the stacked film is smaller than a wavelength of incident light.

2. The solid-state imaging element according to claim 1, wherein
the stacked film group has an optical transparency and a refractive index that gradually changes in a stacking direction.

3. The solid-state imaging element according to claim 2, wherein
at least one of the materials constituting the stacked film has a function of suppressing permeation of hydrogen gas.

4. The solid-state imaging element according to claim 2, wherein
at least one of the materials constituting the stacked film has a function of absorbing light having a specific wavelength.

5. The solid-state imaging element according to claim 4, wherein
at least one of the materials constituting the stacked film has a function of absorbing ultraviolet light.

6. The solid-state imaging element according to claim 2, wherein
at least one of the materials constituting the stacked film has a lower etching rate for a predetermined etching process than a film stacked on a light incident side of the stacked film group.

7. The solid-state imaging element according to claim 2, wherein
at least one of the materials constituting the stacked film functions as a pinning layer for the photoelectric conversion unit.

8. The solid-state imaging element according to claim 2, wherein
at least one of the materials constituting the stacked film has a function of adjusting stress generated in the photoelectric conversion unit.

9. An electronic device comprising:
a solid-state imaging element;
an optical system that captures incident light from an object and forms an image on an imaging surface of the solid-state imaging element; and
a signal processing circuit that performs processing on an output signal from the solid-state imaging element,
the solid-state imaging element including:
a photoelectric conversion unit that converts incident light into an electrical signal; and
a stacked film group provided on a light incident side of the photoelectric conversion unit,
wherein the stacked film group is formed by stacking a plurality of stacked films formed by stacking thin films of different materials, and
an entire film thickness of the stacked film is smaller than a wavelength of incident light.
